(19) United States
(12) Patent Application Publication
(10) Pub. No.: US 2021/0057629 A1
(43) Pub. Date: Feb. 25, 2021

(54) THERMOELECTRIC MODULE FOR POWER GENERATION AND PRODUCTION METHOD THEREFOR

(71) Applicant: Isabellenhuette Heusler GMBH & Co. KG, Dillenburg (DE)

(72) Inventors: Jan MARIEN, Herborn (DE); Daniel ZUCKERMANN, Sinn (DE); Samuel HERBERT, Dillenburg-Manderbach (DE)

(21) Appl. No.: 16/976,271

(22) PCT Filed: Feb. 26, 2019
(86) PCT No.: PCT/EP2019/054652

§ 371 Date: Aug. 27, 2020

(30) Foreign Application Priority Data
Mar. 1, 2018 (DE) 10 2018 104 716.9

(51) Int. Cl. H01L 35/32; H01L 27/16; H01L 35/34; H01L 35/08; F01N 5/02

(52) U.S. Cl. CPC H01L 35/32; H01L 27/16; H01L 35/30; H01L 35/08; F01N 5/025; H01L 35/34

(57) ABSTRACT

The invention relates to a thermoelectric module for thermoelectric current generation, in particular in an exhaust gas system of an internal combustion engine, with a base plate and a plurality of thermocouples each with two legs, the thermocouples being electrically connected in series and mounted on the base plate. The invention provides that the base plate consists of a metallic material. This enables a low-cost production, allows substantially larger formats and makes the thermoelectric module mechanically much less sensitive than a conventional base plate made of ceramic. Furthermore, the invention includes a corresponding production method.

The invention relates to a thermoelectric module for thermoelectric power generation, in particular in an exhaust gas system of an internal combustion engine. Furthermore, the invention relates to a production method for such a thermoelectric module.

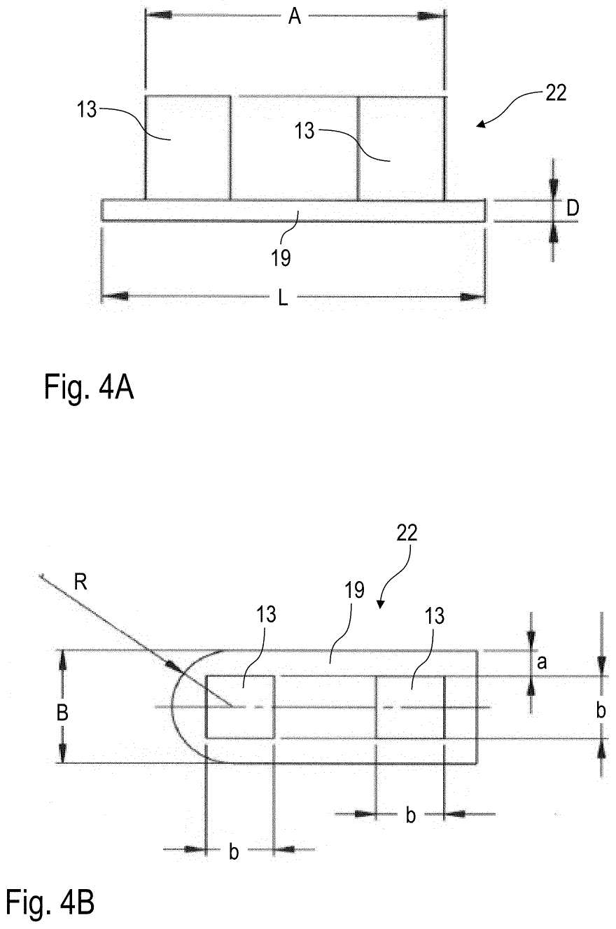

Classical thermoelectric modules for converting thermal energy into electrical energy consist of a series connection of several thermocouples. Each of these thermocouples consists of at least one p-type component (leg), one n-type component (leg) and a contact bridge (FIGS. 4A, 4b) which electrically connects these two components and is usually made of metal. Several thermocouples are connected in series by electrically connecting the p-type component of one thermocouple to the n-type component of the next thermocouple, and so on. Such an interconnection of thermocouples is called a thermoelectric module. By generating a heat flow through the p-type and n-type component from one contact plane to the other contact plane, an electrical voltage is generated by means of the Seebeck effect.

Typical heat sources for such a process are e.g. hot gas flows as they are found in exhaust systems of combustion engines. But any other heat source is also conceivable. For example, in order to extract heat from the exhaust gas and conduct it to the thermocouple or to dissipate residual heat that has not been converted into electrical energy, metallic heat exchanger systems are normally used. To avoid a short circuit between heat exchangers and contact bridges, an electrical insulation of the contact bridges to the heat exchangers is absolutely necessary.

Ceramic plates several tenths of a millimetre thick, e.g. made of aluminium oxide or aluminium nitride, are usually used as insulation. In order to ensure optimum heat transfer between the insulation and the contact bridge, integral joint connections have been established. The use of so-called DBC or DCB (DBC: direct bond copper; DCB: direct copper bond) composite substrates is common. Here copper is laminated directly onto a ceramic plate. These substrates have good electrical insulation and thermal conductivity. However, the disadvantage of these substrates is that their size is limited to about 130 mm×180 mm due to the production method. In addition, solid ceramics do not have plastic deformability and are therefore susceptible to mechanical stress. A further disadvantage of DCB technology is the high production price of the laminates.

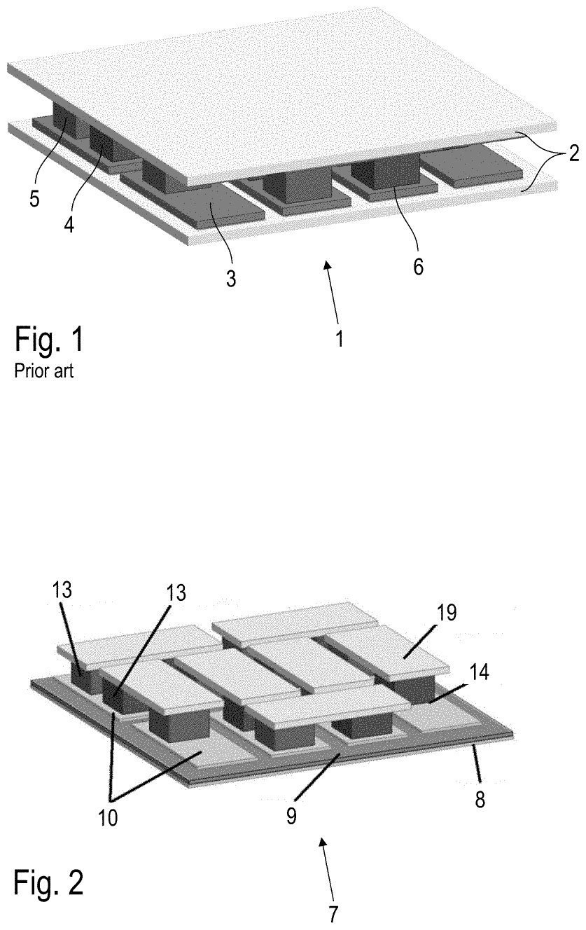

FIG. 1 shows a perspective view of a conventional thermoelectric module 1 for the conversion of thermal energy into electrical energy by means of the Seebeck effect. The thermoelectric module 1 is manufactured according to the DCB bonding technology (DCB: Direct Copper Bond). Thus the known thermoelectric module 1 has two parallel ceramic plates 2, which are arranged on the hot and cold sides respectively. In the drawing, the lower ceramic plate 2 is arranged on the cold side and carries numerous contact pads 3 made of copper, whereby the individual contact pads 3 each electrically contact a p-type leg 4 and an n-type leg 5 in order to electrically connect the individual thermocouples in series. The connection between the p-type legs 4 or the n-type legs 5 and the associated contact pads 3 is made by sintered, adhesive or soldered connections 6.

A disadvantage of the known DCB connection technology is the relatively high manufacturing costs. In addition, the ceramic plates 2 are also sensitive to impact and thermal shock. Finally, the known thermoelectric module 1 is limited in size and lateral expansion.

For the technical background of the invention, reference should also be made to DE 10 2016 006 064 A1, US 2016/0 204 329 A1, US 2011/0 017 254 A1, JP 2005-317 834 A, US 2002/0 189 661 A1 and US 2016/0 315 242A1.

The invention is therefore based on the task of creating a correspondingly improved thermoelectric module.

The thermoelectric module according to the invention initially has a base plate in accordance with the state of the art. It should be mentioned here that the base plate and then also the other layers of the thermoelectric module are preferably flat. However, it is theoretically also possible that the base plate and the other layers are bent.

In addition, in accordance with the state of the art, the thermoelectric module according to the invention contains a large number of thermocouples each with two legs, the thermocouples being electrically connected in series and mounted on the base plate. To avoid misunderstandings, it should be noted that not all thermocouples need to be electrically connected in series in the context of the invention. It is also possible, for example, that the thermocouples are each connected in series in groups, in which case the groups are connected in parallel.

In contrast to the state of the art, however, the base plate of the thermoelectric module according to the invention does not consist of a ceramic material, but of a metallic material (e.g. copper, aluminum, stainless steel).

This offers the advantage that the thermoelectric module can be manufactured more cost-effectively. In addition, much larger formats are possible with a metal plate as a base plate. Finally, the thermoelectric module according to the invention is also mechanically much less sensitive than a ceramic base plate.

In a preferred embodiment of the invention, the metal base plate is arranged on the cold side of the thermoelectric module, i.e. on the side of the thermoelectric module which is exposed to a lower temperature during operation than the opposite hot-side.

In addition, the thermoelectric module has an insulating layer on the cold side, which is arranged between the metallic base plate on the one hand and the thermocouples on the other hand and serves to electrically insulate the metallic base plate from the thermocouples and to fix the thermocouples on the base plate. This insulating layer consists of an organic adhesive layer.

To achieve good thermal conductivity of the organic insulating layer, the insulating layer can be at least partially filled with ceramic material.

Furthermore, according to the invention, the thermoelectric module preferably comprises a plurality of electrically conductive contact pads on the contact-side insulating layer. The individual contact pads each serve to contact two legs of different thermocouples for an electrical series connection of the thermocouples in the thermoelectric module according to the invention.

Furthermore, the thermoelectric module according to the invention preferably has a corrosion protection layer on the cold side, which covers the contact pads on the insulating layer and protects them from corrosion. For example, this corrosion protection layer can consist of a nickel-gold layer, as is known per se from the state of the art.

In addition, an electrical insulating layer (e.g. ceramic layer) is provided on the hot-side to insulate the thermocouples from the electrically conductive heat conducting plate.

A further intermediate layer (e.g. graphite foil) can be placed between the insulating layer on the hot-side and the thermocouples to compensate for surface irregularities.

In addition, a large number of electrically conductive contact pads are provided on the hot-side in order to contact two legs of different thermocouples for electrical series connection of the thermocouples.

The contact pads on the hot-side can also be covered with a corrosion protection layer (e.g. nickel-gold layer) to prevent corrosion of the contact pads.

Furthermore, the invention also comprises a further aspect of invention which enjoys protection independently of the first aspect of invention (metal base plate) described above. Thus, this second aspect of invention provides that the contacting of the thermocouples on the hot-side on the one hand and on the cold side on the other hand takes place at different joining temperatures. The connection between the contact pads on one side and the legs of the thermocouples on the other side is preferably made on the hot-side by a higher joining temperature than on the cold side, for example by a brazing connection at a temperature of 900° C., for example. On the cold side, on the other hand, the connection between the contact pads and the legs of the thermocouples is made at a lower temperature, for example by soft-soldering at a temperature of, for example, 300° C. The brazed joints on the hot-side of the thermoelectric module are useful if the thermoelectric module has to withstand temperatures of up to 600° C. on its hot-side when used in an exhaust gas system of an internal combustion engine. A brazing alloy (e.g. a silver-based brazing alloy) is required for this purpose, whereas a soft-soldered joint would not withstand these relatively high temperatures. On the cold side of the thermoelectric module, on the other hand, temperatures during operation are only up to a maximum of 150° C., so that soft-soldered joints are sufficient there.

The individual thermocouples are therefore preferably pre-assembled first, whereby a brazed joint is made during pre-assembly. The pre-assembled, brazed thermocouples are then mounted on the base plate and contacted by a soft-soldered joint. With this soft-soldered joint, the entire thermoelectric module only needs to be heated to about 300° C., which is considerably less than with a brazed joint. This reduces the mechanical stresses in the thermoelectric module. In addition, these temperature reductions during the production method reduce manufacturing costs. Furthermore, substantially larger modules are also possible. Finally, the pairs of legs can also be used for different module types, which enables standardization.

In addition to the two aspects of the invention mentioned above (metal base plate, brazing on the hot-side and soft soldering on the cold side), the invention also includes a third aspect of invention which is described below.

This third aspect of the invention is based on the realization that the operating temperature on the hot-side of the thermoelectric module varies spatially, so that it is useful to adapt the individual thermocouples to the locally prevailing operating temperatures depending on their mounting location within the thermoelectric module. It is therefore preferable that the thermocouples are made of different thermoelectric materials, which are designed for different operating temperatures for the different thermocouples.

In the preferred embodiment of the invention, the thermoelectric module is subjected to a temperature gradient parallel to the hot-side during operation on the hot-side, so that the temperature on the hot-side of the thermoelectric module decreases from a high temperature zone to a low temperature zone. The thermocouples in the high temperature zone are then preferably designed for a higher operating temperature than in the low temperature zone.

For example, the thermocouples in the high-temperature range may consist at least partly of high-temperature-stable half-Heusler alloys, skutterudite, silicide or lead telluride, while the thermocouples in the low-temperature range consist at least partly of bismuth telluride.

The structure of the thermoelectric module according to the invention allows a very large number of thermocouples in the thermoelectric module, whereby the number of thermocouples can be greater than 100, 200, 400 or even greater than 600, for example.

The individual contact pads for the thermocouples can have a length of 2 mm-10 mm, a width of 0.5 mm-4 mm and a thickness of 0.1 mm-1 mm, for example.

The individual legs of the thermocouples can each have a thickness of 0.3 mm-3 mm and a length of 0.3 mm-3 mm.

For example, the base plate of the thermoelectric module can have an edge length of at least 2 cm, 4 cm or even 15 cm.

With regard to the insulating layer on the metallic base plate, it should be mentioned that this can have a layer thickness of 5 μm-100 μm, for example.

The metallic material of the metallic base plate can be copper, a copper alloy, aluminium, an aluminium alloy or stainless steel, to name but a few examples. However, the invention is not limited to these examples with respect to the metallic material of the metallic base plate.

It should also be noted that the invention does not only claim protection for the thermoelectric module described above as a single component. Rather, the invention also claims protection for a complete exhaust gas system of an internal combustion engine with such a thermoelectric module for generating electricity from the waste heat of the hot gas flow.

Furthermore, the invention also claims protection for a complete internal combustion engine (e.g. Otto engine, diesel engine) with an exhaust gas system in which a thermoelectric module according to the invention is arranged.

Finally, the invention also claims protection for a corresponding production method. The individual process steps of the production method according to the invention result from the above description of the thermoelectric module, so that a separate description of the individual process steps is not necessary.

Other advantageous further developments of the invention are indicated in the dependent claims or are explained in more detail below together with the description of the preferred embodiment of the invention using the figures. They show:

FIG. 1 a perspective view of a conventional thermoelectric module for power generation,

FIG. 2 a perspective view of a section of a thermoelectric module according to the invention,

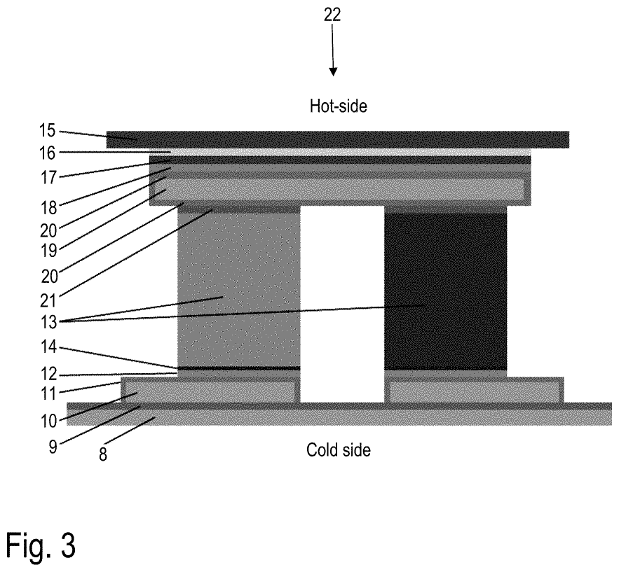

FIG. 3 a sectional view through a thermocouple of the thermoelectric module according to the invention to illustrate the layered structure,

FIG. 4A a side view of a single thermocouple of the thermoelectric module of the invention,

FIG. 4B a view of the thermocouple as shown in FIG. 4A,

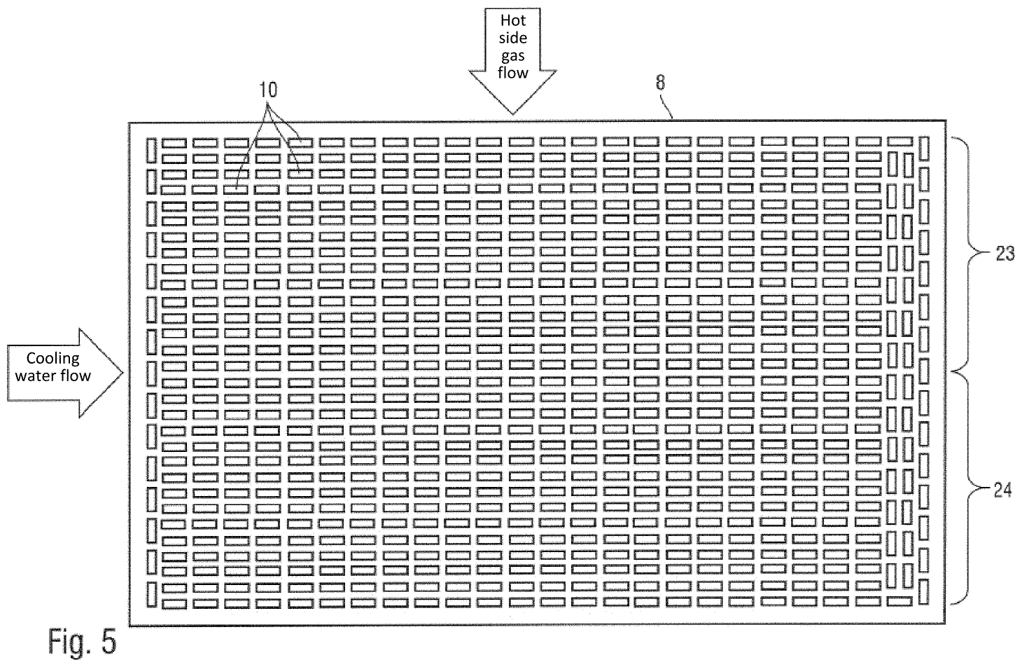

FIG. 5 shows a view of a metallic base plate of the thermoelectric module according to the invention,

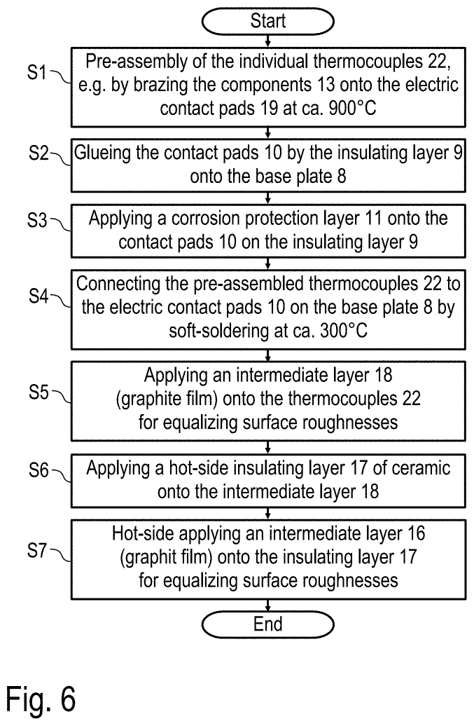

FIG. 6 a flow chart explaining the production method according to the invention, and

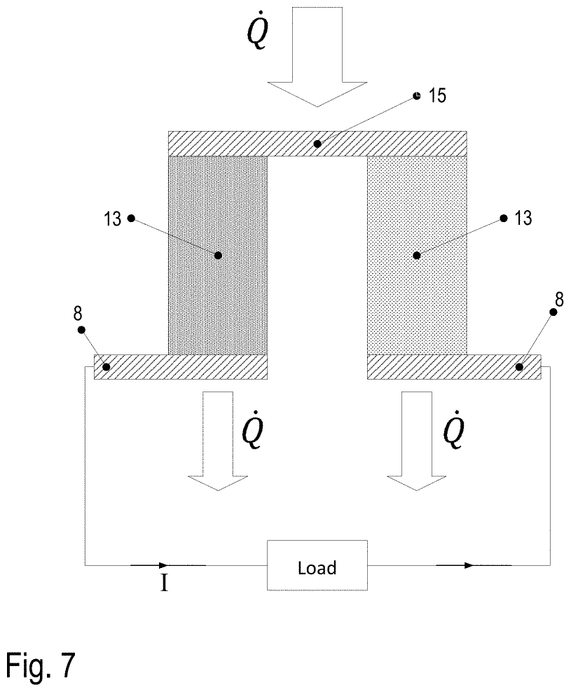

FIG. 7 is a schematic diagram of a thermocouple used to supply power to an electrical load.

FIGS. 2 to 5 show different views of a thermoelectric module 7 according to the invention, which can be used, for example, for thermoelectric power generation by exposing the thermoelectric module 7 to a hot exhaust gas system of a combustion engine (e.g. Otto engine, diesel engine).

The thermoelectric module 7 according to the invention initially has a cold-side base plate 8 made of metal (e.g. copper, aluminium, stainless steel).

The metal base plate 8 carries an electrically insulating layer 9 of an organic adhesive, so that the contact pads 10 can be easily glued to the base plate 8.

Electrically conductive contact pads 10 are applied to the insulating layer 9, which are covered by a corrosion protection layer 11 (e.g. nickel-gold layer) to prevent corrosion of the contact pads 10. The insulating layer 9 prevents a short circuit between the contact pads 10 via the electrically conductive base plate 8.

In the thermoelectric module 7, the legs 13 of the thermocouples 22 are connected to the cold-side contact pads 11 by a soft-soldered connection 12.

Adjacent to the hot-side of the thermoelectric module 7 is first of all a heat conducting plate 15, which can be made of stainless steel, for example, and serves for thermal coupling to the heat source to be used (e.g. hot gas flow). This heat conducting plate does not belong to the actual thermoelectric module itself and is only shown for illustration purposes.

Underneath it there is an intermediate layer 16, which may consist of a graphite foil, for example, and has the task of compensating for surface unevenness.

This is followed by an insulating layer 17, which is made of ceramic to withstand the high temperatures occurring on the hot-side of the thermoelectric module 7.

Next, an optional intermediate layer 18 is then added to compensate for surface unevenness. This layer can consist of graphite, boron nitride or a metallic solder, for example.

This is followed by the individual contact pads 19, which in turn are coated with a corrosion protection layer (e.g. nickel-gold layer). The insulating layer 17 prevents a short circuit between the contact pads 19 via the electrically conductive heat conducting plate 15.

The connection between the legs 13 of the individual thermocouples on the one hand and the hot-side contact pads 19 on the other hand is made here, for example, by brazing joints 21, which can withstand the high temperatures occurring on the hot-side of the thermoelectric module 7.

FIG. 3 shows a sectional view of a single thermocouple 22, but FIG. 5 shows that the base plate 8 carries a number of contact pads 10, so that the thermoelectric module 7 can contain a number of thermocouples 22 connected in series.

FIGS. 4A and 4B show that the hot-side contact pads 19 can have, for example, a length L=4.5 mm, a thickness D=0.3 mm and a width B=1.8 mm.

The individual legs 13 of thermocouples 22 can each have a thickness of b=1 mm.

Furthermore, it is evident that the contact pads 19 on the heat side can have a radius R=0.9 mm, whereby the rounded side enables alignment detection.

FIG. 5 further shows that the thermoelectric module 7 is exposed to a hot gas flow, which in the drawing runs in a vertical direction from top to bottom. On the cold side of the thermoelectric module 7, on the other hand, a cooling water flow runs in the horizontal direction from left to right in the drawing. This means that the temperature on the hot-side of the thermoelectric module 7 is not uniform. Rather, the temperature in a high temperature zone 23 is higher than in a subsequent low temperature zone 24 on the hot-side of the thermoelectric module 7. The individual thermocouples 22 are therefore adapted to the locally fluctuating operating temperatures. The thermocouples 22 in the high-temperature range 23, for example, are made of half Heusler alloys, which are extremely stable at high temperatures. The thermocouples 22 in the low temperature zone 24, on the other hand, consist of bismuth tellurides, which are optimized for lower temperature ranges.

In the following, the production method according to the invention is described, which is shown in FIG. 6 in the form of a flow chart.

In a first step S1, the individual thermocouples 22 are first manufactured, in which the legs 13 are connected to the hot-side contact pads 19, for example, by a brazed joint. In order to avoid misunderstandings, it should be said that any other joining technology, such as sintering, is also possible, which meets the requirements for electrical conductivity and temperature stability. The brazed joint on the hot-side of the thermoelectric module 7 is advantageous because the thermoelectric module 7 can then be exposed to very high operating temperatures on the hot-side.

In a step S2 the contact pads 10 are glued through the insulating layer 9 onto the base plate 8.

In a step S3 the corrosion protection layer 11 is then applied to the contact pads 10.

In a step S4 the pre-assembled thermocouples 22 are then connected to the electrical contact pads 10 on the cold side. This connection is made, for example, by soft soldering at about 300° C. It is important that the joining temperature during this process is lower than the temperature that would be necessary to release the pre-assembly of the thermocouples. A soft-soldering process that is advantageous here produces much lower temperatures than a brazing process on the hot-side of the thermoelectric module 7. This has the advantage that the thermoelectric module 7 only needs to be heated to about 300° C. This also reduces the mechanical stresses in the thermoelectric module 7 that arise during the brazing process. A further advantage is the reduction of manufacturing costs and larger thermoelectric modules 7 are possible. Finally, the individual pairs of legs can also be used for different module types, which allows standardization.

On the hot-side, the intermediate layer 18 is then optionally applied in a step S5 to compensate for surface unevenness.

In a step S6, the hot-side insulating layer 17 made of ceramic is then applied. The use of ceramic as the material for the insulating layer 17 is important because very high temperatures occur on the hot-side, so that the insulating layer 17 must be correspondingly temperature-resistant.

Then, in a step S7, the intermediate layer 16 is applied to compensate for surface unevenness.

The spaces between the legs 13 of the individual thermocouples 22 remain empty and are thus filled with air during operation, which provides good thermal insulation. Optionally, however, the inter-spaces can also be filled with a highly heat-insulating solid material, such as a fiber cement.

The schematic diagram in FIG. 7 shows that the legs of the thermocouple touch a metallic contact on the cold side and on the hot-side. The heat flow dQ/dt from the hot-side heat conducting plate 15 to the cold-side base plate 8 is the result of a corresponding temperature difference, which generates a corresponding thermoelectric voltage.

The invention is not limited to the preferred embodiment described above. Rather, a large number of variants and modifications are possible which also make use of the inventive idea and therefore fall within the scope of protection. In particular, the invention also claims protection for the subject matter and the features of the dependent claims independently of the claims referred to in each case and in particular even without the features of the main claim. Furthermore, it should be mentioned that the invention comprises the following aspects of the invention which are protected independently of each other:
Base plate made of metal instead of ceramic,
brazed joint on the hot-side and soft soldered joint on the cold side,
different thermocouple materials depending on the local fluctuation of the operating temperature

These aspects of the invention can therefore enjoy protection independently of each other.

### LIST OF REFERENCES SIGNS

1 Thermoelectric module according to the state of the art

2 Ceramic plates

3 Contact pads

4 p-type legs of the thermocouples

5 n-type legs of the thermocouples

6 Soldered connection

7 Thermoelectric module according to the invention

8 Cold-side base plate made of metal (e.g. copper)

9 Insulating layer of adhesive

10 Cold side contact pads

11 Corrosion protection layer on the cold side contact pads

12 Cold-side graphite intermediate layer to compensate for surface unevenness

13 Legs of the thermocouples

14 Soft-solder connection on the cold side

15 Heat conducting plate on the hot-side

16 Hot-side intermediate layer of graphite to compensate for surface unevenness

17 Hot-side ceramic insulating layer

18 Hot-side intermediate layer of graphite to compensate for surface unevenness

19 Hot-side contact pads

20 Hot-side corrosion protection layer on the hot-side

21 Brazed joint on the hot-side

22 Thermocouple

23 High temperature zone on the hot-side of the thermoelectric module

24 Low temperature zone on the hot-side of the thermoelectric module

1-16. (canceled)

17. Thermoelectric module for thermoelectric power generation, with
a) a base plate; and
b) a plurality of thermocouples each having two legs, the thermocouples being at least partially electrically connected in series and mounted on the base plate,
c) wherein the base plate consists of a metallic material.

18. Thermoelectric module according to claim 17, wherein the thermoelectric module has a hot-side and a cold side, the metallic base plate being arranged on the cold side of the thermoelectric module.

19. Thermoelectric module according to claim 18, further comprising a cold-side insulating layer between the metallic base plate on the one hand and the thermocouples on the other hand for electrically insulating the metallic base plate from the thermocouples.

20. Thermoelectric module according to claim 19, wherein the cold-side insulating layer includes an adhesive layer bonded to the metallic base plate.

21. Thermoelectric module according to claim 19, wherein the cold-side insulating layer is at least partially filled with ceramic material to achieve good thermal conductivity of the insulating layer.

22. Thermoelectric module according to claim 19, further comprising a plurality of electrically conductive contact pads on the cold-side insulating layer for electrically contacting two legs of different thermocouples for an electrical series connection of the thermocouples.

23. Thermoelectric module according to claim 19, further comprising a cold-side corrosion protection layer which covers the contact pads on the cold-side insulating layer and protects them from corrosion.

24. Thermoelectric module according to claim 19, further comprising a hot-side heat conducting plate for thermal coupling of the thermoelectric module to a heat source.

25. Thermoelectric module according to claim 24, further comprising a hot-side first intermediate layer between the heat conducting plate and the thermocouples for compensating surface unevenness.

26. Thermoelectric module according to claim 24, further comprising a hot-side insulating layer for electrically insulating the thermocouples with respect to the heat conducting plate.

27. Thermoelectric module according to claim 24, further comprising a hot-side second intermediate layer between the hot-side insulating layer and the thermocouples for compensating surface unevenness.

28. Thermoelectric module according to claim 19, further comprising a plurality of hot-side, electrically conductive contact pads for electrically contacting two legs of different thermocouples for an electrical series connection of the thermocouples.

29. Thermoelectric module according to claim 28, further comprising a hot-side corrosion protection layer on the hot-side contact pads for protecting the hot-side contact pads against corrosion.

30. Thermoelectric module according to claim 17, further comprising
a) a plurality of electrically conductive contact pads on the hot-side of the thermoelectric module for electrically contacting two legs of different thermocouples for an electrical series connection of the thermocouples, wherein the hot-side contact pads are connected to the legs of the thermocouples by a brazing connection, and
b) a plurality of electrically conductive contact pads on the cold side of the thermoelectric module for electrically contacting in each case two legs of different thermocouples for an electrical series connection of the thermocouples, wherein the cold-side contact pads are connected by a soft-solder connection to the legs of the thermocouples.

31. Thermoelectric module according to claim 17, wherein the thermocouples include different thermoelectric materials which are designed for different operating temperatures in the different thermocouples.

32. Thermoelectric module according to claim 31, wherein
a) the thermoelectric module in operation is exposed to a temperature gradient on the hot-side parallel to the hot-side, so that the temperature on the hot-side of the thermoelectric module decreases from a high temperature zone to a low temperature zone, and
b) the thermocouples in the high temperature zone are designed for a higher operating temperature than in the low temperature zone.

33. Thermoelectric module according to claim 32, wherein the thermocouples in the high temperature zone consist at least partially of one of the following materials:
a1) high-temperature stable half Heusler alloy,
a2) Skutterudit,
a3) Silicide,
a4) lead telluride.

34. Thermoelectric module according to claim 32, wherein the thermocouples in the low temperature zone consist at least partially of bismuth telluride.

35. Thermoelectric module according to claim 17, wherein
a) the number of thermocouples in the thermoelectric module is greater than 100,
b) the individual contact pads for the thermocouples each have a length of 2 mm-10 mm,
c) the individual contact pads for the thermocouples each have a width of 0.5 mm-4 mm,
d) the individual contact pads for the thermocouples each have a thickness of 0.1 mm-1 mm,
e) the individual legs of the thermocouples each have a thickness of 0.5 mm-2 mm,
f) the individual legs of the thermocouples each have a length of 0.5mm-3mm,
g) the base plate has an edge length of at least 2 cm,
h) the insulating layer on the metallic base plate has a layer thickness of 10 μm-100 μm, and
i) the metallic material of the metallic base plate is one of the following materials
i1) copper or copper alloy,
i2) aluminium or aluminium alloy, and
i3) stainless steel.

36. Exhaust gas system of an internal combustion engine for diverting a hot gas flow from the internal combustion engine, with a thermoelectric module which is arranged in the hot gas flow, wherein the thermoelectric module is designed according to claim 17.

37. Exhaust gas system according to claim 36, wherein
a) the thermoelectric module is exposed on its cold side to a coolant flow, which is aligned transversely to the hot gas flow on the hot-side of the thermoelectric module,
b) a temperature gradient transverse to the coolant flow occurs on the hot-side of the thermoelectric module, so that the temperature on the hot-side of the thermoelectric module decreases from a high temperature zone to a low temperature zone, and
c) the thermocouples in the high temperature zone are designed for a higher operating temperature than in the low temperature zone.

38. Internal combustion engine with an exhaust gas system according to claim 36.

39. Production method for a thermoelectric module for thermoelectric power generation comprising the following steps:
a) provision of a base plate,
b) mounting a plurality of thermocouples on the base plate, and
c) wherein the base plate consists of a metallic material.

40. Production method according to claim 39, further comprising at least one of the following steps:
a) application of a cold-side insulating layer to the metallic base plate for electrically insulating the metallic base plate from the thermocouples, the base plate being arranged on the cold side,
b) applying a plurality of electrically conductive contact pads to the insulating layer,
c) applying a corrosion protection layer to the contact pads,
d) applying an intermediate layer to the contact pads to compensate for surface unevenness,
e) mounting the thermocouples on the contact pads on the insulating layer, and/or
f) applying a first intermediate layer to the thermocouples for compensating surface unevenness,
g) applying a hot-side insulating layer for electrical insulation,
h) applying a second intermediate layer to the insulating layer to compensate for surface unevenness, and
i) applying a hot-side heat conducting plate for thermal coupling of the thermoelectric module to a heat source.

41. Production method according to claim 39, further comprising the following steps:
a) connecting each two legs of a thermoelectric material with an electrically conductive contact pad by brazing to form a thermocouple, and
b) connecting the thermocouple to the cold side base plate by soft soldering.

42. Production method according to claim 41, wherein
a) the thermocouples are pre-assembled individually, and
b) the pre-assembled thermocouples are then connected together with the metallic base plate.

43. Production method according to claim 39, wherein
a) the thermoelectric module is subjected in operation to a temperature gradient parallel to the hot-side, so that the temperature on the hot-side of the thermoelectric module decreases from a high temperature zone to a low temperature zone, and
b) the thermocouples in the high temperature zone are designed for a higher operating temperature than in the low temperature zone.
